(19) United States
(12) Patent Application Publication
(10) Pub. No.: US 2002/0048945 A1
(43) Pub. Date: Apr. 25, 2002

(54) Method for manufacturing semiconductor devices

(76) Inventors: Yoshikazu Ibara, Gifu-ken (JP); Kei-ichi Yamaguchi, Giku-ken (JP)

Correspondence Address: ARMSTRONG,WESTERMAN & HATTORI, LLP, 1725 K STREET, NW., SUITE 1000, WASHINGTON, DC, 20006, US

(21) Appl. No.: 09/892,893

(22) Filed: Jun. 28, 2001

(30) Foreign Application Priority Data
Jul. 3, 2000 (JP) 2000-201248

(51) Int. Cl. H01L 21/28; H01L 21/44

(52) U.S. Cl. 438/682; 438/755; 438/581; 438/583

(57) ABSTRACT

A method for manufacturing a miniaturized semiconductor device having a conductive portion with a silicide structure. The manufacturing method includes depositing metal on the surface of a patterned semiconductor film to form the conductive portion, heat treating the semiconductor film on which the metal is deposited, removing the residual metal that did not react during the heat treatment, and repeating the depositing step, the heat treating step, and the removing step once or a number of times.

### BACKGROUND OF THE INVENTION

The present invention relates to a method for manufacturing semiconductor devices, and more particularly, to a method for forming silicide on a conductive portion of a semiconductor device.

Due to the recent trend of higher integration of semiconductor devices, the significance of miniaturizing semiconductor elements that are connected to the semiconductor devices has increased. However, the miniaturization of the elements has resulted in resistance being produced in the conductive portion of electrodes. Further, resistivity differs between the elements. For example, in a MOS transistor, the line resistance and parasitic resistance at the conductive portions of the gate, source, and drain are large. As the element gets smaller, the line delay and conductance deterioration resulting from the electric resistance at the conductive portions becomes such that it cannot be ignored. In the prior art, silicide is applied to the surface of each electrode by combining metal elements on the electrode surface. This prevents line delay and conductance deterioration. Salicide structures, in which silicide is applied to the surface of the electrodes in a selective and self-aligning manner, are also often employed.

Salicide is normally applied in the manner described below.

(a) A silicon oxide (SiO₂) spacer is formed on the side walls of a polycrystalline silicon gate electrode.

(b) Subsequently, metal is deposited on the entire surface of the element. The deposited metal is heat treated and silicide is applied to the conductive portions of the gate, source, and drain in a self-aligning manner.

(c) Residual non-reactive metals are removed.

In process (b), the application of the silicide is performed through solid phase diffusion. As a result, bridging occurs during the formation of the silicide. Bridging refers to the formation of a silicide film on the spacer or an element partitioning area. When bridging occurs during the silicide application process, the silicide substance conducts electricity between conductive portions even when an insulative material is provided between the conductive portions. As a result, the semiconductor element fails to function. When the size of the semiconductor element is decreased, bridging tends to occur when, for example, the gate is thin.

Normally, when manufacturing a semiconductor device having a salicide structure, heat treatment is performed once in a temperature range in which bridging does not occur to apply silicide to the conductive portions. After the non-reactive metals are removed, an additional heat treatment is performed. That is, a silicide film having high resistance is temporarily formed on the conductive portions in a temperature range in which bridging does not occur. The removal of the non-reactive metals eliminates conductive substances from the insulative film. The additional heat treatment reforms the high resistance silicide film to a low resistance silicide film.

As the size of the semiconductor devices becomes smaller, the sheet resistivity of the element electrodes increases as the conductive portions to which silicide is applied becomes smaller. This phenomenon is referred to as the fine line effect. When the size of the semiconductor device is so small that the fine line effect occurs, it is difficult to form the silicide film with the desired resistance characteristic even when performing the heat treatment twice during the formation of the salicide. Accordingly, due to the decrease in the size of the semiconductor devices, a need for various improvements has arisen to form the silicide structure appropriately.

### SUMMARY OF THE INVENTION

It is an object of the present invention to provide a method for manufacturing a miniaturized semiconductor device having conductive portions provided with a silicide structure.

To achieve the above object, the present invention provides a method for forming a silicide conductive structure on a semiconductor device. The method includes depositing metal on the surface of a patterned semiconductor film, heat treating the semiconductor film on which the metal is deposited, removing residual metal that did not react during the heat treating step, and repeating the depositing step, the heat treating step, and the removing step once or a number of times.

A further perspective of the present invention is a method for manufacturing a semiconductor device. The method includes forming a conductive portion on the substrate. The conductive portion has a gate electrode. The method further includes forming a spacer on a side wall of the gate electrode, depositing metal on the surface of the substrate including the conductive portion, applying silicide on the conductive portion in a self-aligned manner by heat treating the substrate on which the metal is deposited, removing residual metal that did not react during the heat treatment, and repeating the depositing step, the silicide applying step, and the removing step once or a number of times.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIGS. 1A to 1E are schematic cross-sectional views showing the procedure for manufacturing semiconductor devices according to the present invention;

FIG. 2 is a graph showing the relationship between the width and sheet resistivity of the silicide film formed on an N-type semiconductor; and

FIG. 3 is a graph showing the relationship between the width and sheet resistivity of the silicide film formed on a P-type semiconductor.

### DETAILED DESCRIPTION OF THE PREFERRED EMBODIMENTS

In the drawings, like numerals are used for like elements throughout.

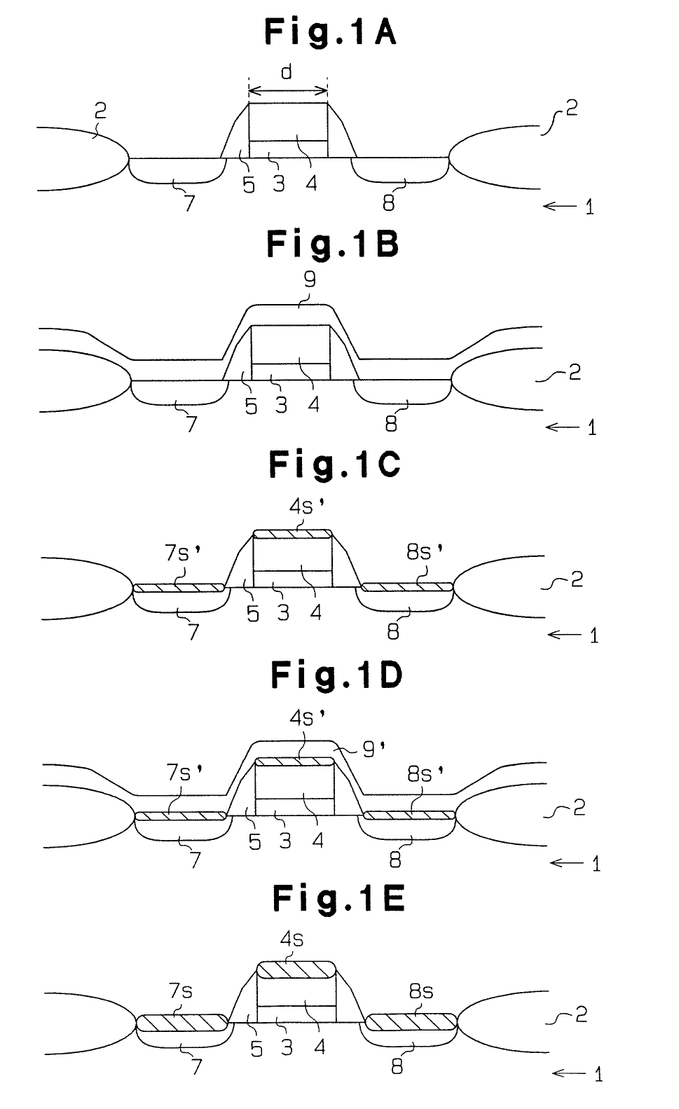

FIGS. 1A to 1E are cross-sectional views showing the procedure for manufacturing a semiconductor device according to the present invention. In the preferred embodiment, the present invention is embodied in a method for manufacturing a metal oxide semiconductor (MOS) transistor.

Referring to FIG. 1A, insulative portions 2, 3, 5 and conductive portions 4, 7, 8 are formed on a silicon substrate 1 in accordance with a MOS transistor manufacturing method, which is known in the art.

For example, an oxide partitioning film 2, which is formed from silicon oxide (SiO₂), separates the substrate 1 into element sections. A gate oxide film 3 and a polysilicon film, each having width d (in this example, 0.25 μm), are superimposed in each element section. The gate oxide film 3 is formed from SiO₂ and the polysilicon film defines a gate electrode 4. Further, a spacer 5, which is made of Si0₂, is formed on the side wall of the gate oxide film 3 and the polysilicon film. N-type impurities are applied to the surface of the substrate 1 to form the gate electrode 4, a source section 7, and a drain section 8, which are conductive portions.

Referring to FIG. 1B, after the formation of the insulative and conductive portions, a titanium thin film 9 having a thickness of 300 Å (10⁻⁸ cm) is superimposed on the insulative and conductive portions through sputtering. Then, a rapid thermal annealing (RTA) apparatus is used to perform heat treatment in a nitrogen (N₂) atmosphere for ten seconds at 700° C. Afterward, a solution of ammonia and hydrogen peroxide is used to remove titanium that did not react with the conductive portions 4, 7, 8. Referring to FIG. 1C, in this manner, high resistance titanium silicide films 4s′, 7s′, 8s′, which are made of C49 phases, are respectively applied to the surfaces of the gate electrode 4, the source section 7, and the drain section 8.

Referring to FIG. 1D, a titanium thin film 9′ having a thickness of 300 Å (10⁻⁸ cm) is superimposed again on the titanium silicide films 4s′, 7s′, 8s′. A heat treatment is then performed again in an N₂ atmosphere for ten seconds at 700° C. by the RTA apparatus. Subsequently, the solution of ammonia and hydrogen peroxide is used to remove the titanium that did not react with the titanium. In this state, high resistance titanium silicide films that are made of the C49 phase and are sufficiently thick are respectively formed on the surfaces of the gate electrode 4, the source section 7, and the drain section 8. Afterward, an additional heat treatment is performed in a nitrogen (N₂) atmosphere for 30 seconds at 850° C. by the RTA apparatus. Referring to FIG. 1E, this forms low resistance titanium silicide films 4s, 7s, 8s, which are made of a C54 phase, on the surfaces of the gate electrodes 4, the source section 7, and the drain section 8.

In the following step, the MOS transistor is manufactured through a manufacturing method that is known in the art.

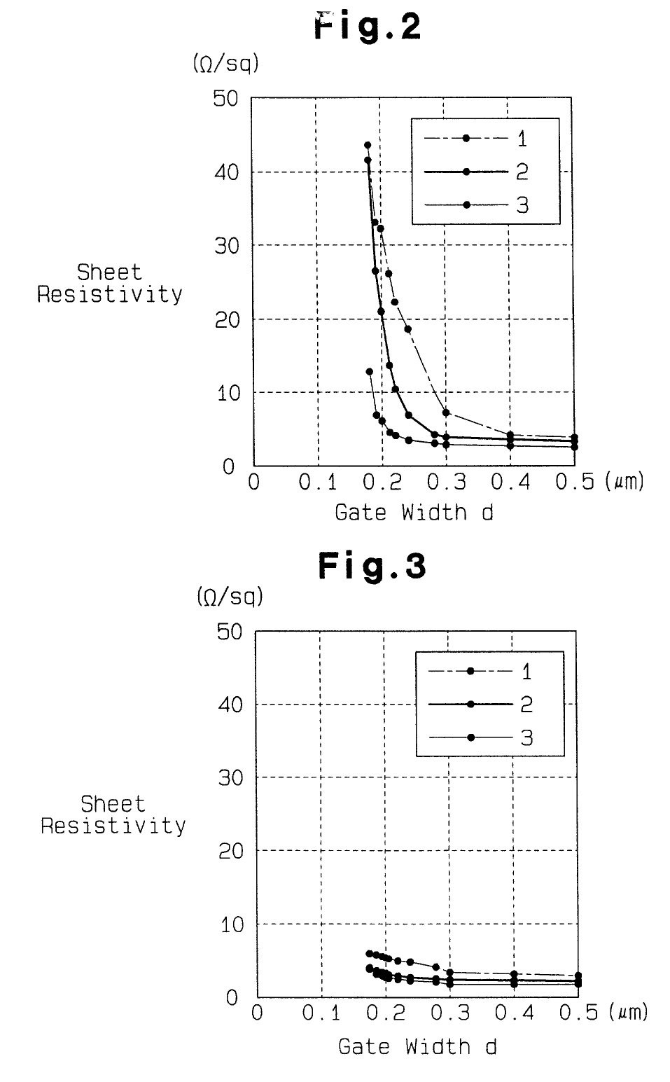

The features of the titanium silicide films 4s, 7s, 8s that are obtained through the manufacturing method of the preferred embodiment will now be discussed. FIG. 2 shows the relationship between the gate width and the sheet resistivity of the silicide film formed on the gate electrode. Further, the results obtained through an experiment conducted by the inventor are shown in FIG. 2. The broken line of FIG. 2 represents the results obtained when the three steps described below are performed once. The bold line of FIG. 2 represents the results obtained when the three steps were performed twice. The fine line of FIG. 2 represents the results obtained when the three steps were performed three times. The three steps are:

(1) superimposing a titanium thin film;

(2) performing heat treatment in an N₂ atmosphere for ten seconds at 700° C.; and

(3) removing residual non-reactive titanium subsequent to the heat treatment. The width d (FIG. 1A) of the film refers to the length of the short side of the gate, which normally forms a rectangular plane.

As shown in FIG. 2, an increase in the sheet resistivity of the silicide film resulting from a decrease in the gate width is less when the three steps are performed twice in comparison to when the three steps are performed once. If the three steps are performed three times, the increase in the sheet resistivity of the silicide film is further suppressed. The C54 phase, low resistance, titanium silicide film is formed by repeating the three steps twice. Thus, if the gate width d is about 0.25 μm, the appropriate number of times for repeating the three steps is two. In addition, if the semiconductor device is further miniaturized, it is preferred that the three steps be performed three times or more.

The method for manufacturing the semiconductor device according to the present invention will now be discussed.

(1) The three steps including the superimposition of the titanium thin film, the heat treatment for ten seconds at 700° C., and the removal of the non-reactive titanium are repeated twice. This prevents bridging and ensures the formation of silicide.

(2) After removing the non-reactive titanium for the second time, the additional heat treatment is performed. This forms the C54 , low resistance, titanium silicide film.

(3) Heat treatment is performed in an N₂ atmosphere. This optimally suppresses differences in the thickness of the titanium film formed through the reaction between titanium and silicon. As a result, silicide is formed in a further optimal manner.

It should be apparent to those skilled in the art that the present invention may be embodied in many other specific forms without departing from the spirit or scope of the invention. Particularly, it should be understood that the present invention may be embodied in the following forms.

The heat treatment may be performed in an argon atmosphere or an ammonia atmosphere. Alternatively, a reaction between titanium and silicon may be produced by supplying heat energy to the substrate 1 instead of putting the substrate 1 in an N₂, argon, or ammonia atmosphere.

The conditions for forming the titanium thin film and performing heat treatment may be changed as required. For example, when manufacturing a semiconductor device that includes an element having a gate electrode, the thickness of which is about 1,000 Å (10⁻⁸ cm) to 2,500 Å (10⁻⁸ cm), it is preferred that a titanium thin film of 200 Å (10⁻⁸ cm) to 400 Å (10⁻⁸ cm) be deposited each time and that the heat treatment be performed for ten seconds at about 600° C. to 720° C. Further, the heat treating time may be changed as required. In this case, the temperature used for the heat treatment should be controlled by, for example, providing the titanium thin film and its surroundings with a constant amount of heat energy.

The condition of the additional heat treatment may be changed as required. For example, when manufacturing a semiconductor device that includes a gate electrode thickness of 1,000 Å (10⁻⁸ cm) to 2,500 Å (10⁻⁸ cm), it is preferred that heat treatment be performed for 10 to 60 seconds at a temperature of 800° C. to 900° C.

The heat treatment does not necessarily have to be performed by the RTA apparatus. For example, a heater or a laser may be used to perform the heat treatment. It is only required that heat energy be provided to the titanium thin film and its surroundings.

The present invention may be applied when forming silicide on the surface of a P-type semiconductor. When silicide is applied to the surface of the P-type semiconductor surface, the relationship between the width and sheet resistivity of the silicide film on a gate electrode surface is shown in FIG. 3. Although the fine line effect does not easily occur when applying silicide to the surface of a P-type semiconductor surface, an increase in the sheet resistivity resulting from a decrease in the gate width is suppressed. In this case, the superimposition of the titanium film, the heat treatment in an N₂ atmosphere for ten seconds at 700° C., and the removal of the non-reactive titanium are repeated for a certain number of times.

The additional heat treatment subsequent to the removal of the non-reactive titanium need not be performed.

To form silicide, metals commonly used to form salicide, such as cobalt (Co) and nickel (Ni), may be used. Further, to form silicide, metals such as molybdenum (Mo), tungsten (W), tantalum (Ta), hafnium (Hf), zirconium (Zr), niobium (Nb), vanadium (V), rhenium (Re), chromium (Cr), platinum (Pt), iridium (Ir), osmium (Os), and rhodium (Rh) may be used.

The present invention may be applied to a method for manufacturing a semiconductor device that forms silicide by having metal react with semiconductor through heat treatment.

The present examples and embodiments are to be considered as illustrative and not restrictive, and the invention is not to be limited to the details given herein, but may be modified within the scope and equivalence of the appended claims.

What is claimed is:

1. A method for forming a silicide conductive structure on a semiconductor device, the method comprising:
depositing metal on the surface of a patterned semiconductor film;
heat treating the semiconductor film on which the metal is deposited;
removing residual metal that did not react during the heat treating step; and
repeating the depositing step, the heat treating step, and the removing step once or a number of times.

2. The method for manufacturing the semiconductor device according to claim 1, further comprising:
heat treating the semiconductor film after the repeating step at a temperature that is higher than that of the heat treating step.

3. The method for manufacturing the semiconductor device according to claim 2, wherein the patterned semiconductor film is an N-type semiconductor.

4. A method for manufacturing a semiconductor device, comprising:
forming a conductive portion on the substrate, wherein the conductive portion includes a gate electrode;
forming a spacer on a side wall of the gate electrode;
depositing metal on the surface of the substrate including the conductive portion;
applying silicide on the conductive portion in a self-aligned manner by heat treating the substrate on which the metal is deposited;
removing residual metal that did not react during the heat treatment; and
repeating the depositing step, the silicide applying step, and the removing step once or a number of times.

5. The method for manufacturing the semiconductor device according to claim 4, further comprising:
heat treating the substrate after the repeating step at a temperature that is higher than that of the heat treating step.

6. The method for manufacturing the semiconductor device according to claim 5, wherein the conductive portion to which silicide is applied is an N-type semiconductor.

7. The method for manufacturing the semiconductor device according to claim 4, wherein the thickness of the gate electrode is 1,000 Å (10⁻⁸ cm) to 2,500 Å (10⁻⁸ cm), and the heat treating is repeated in a temperature range of 600° C. to 720° C.

8. The method for manufacturing the semiconductor device according to claim 7, further comprising:
heat treating the substrate after the repeating step for 30 seconds at a temperature of about 850° C.

9. The method for manufacturing the semiconductor device according to claim 8, wherein the conductive portion to which silicide is applied is an N-type semiconductor.
